(19) United States
(12) Patent Application Publication
(10) Pub. No.: US 2023/0061365 A1
(43) Pub. Date: Mar. 2, 2023

(54) PRINTED CIRCUIT BOARD CORNER CONNECTION

(71) Applicant: Interplex NAS Electronics GmbH, Heilbronn (DE)

(72) Inventor: Hans-Jörg HAHN, Pforzheim (DE)

(21) Appl. No.: 17/799,952

(22) PCT Filed: Oct. 20, 2020
(86) PCT No.: PCT/EP2020/079487

§ 371 Date: Aug. 16, 2022

(30) Foreign Application Priority Data
Feb. 17, 2020 (DE) 102020104100.4

(51) Int. Cl. H01R 12/58; H05K 3/36; H01R 43/02

(52) U.S. Cl. CPC H01R 12/585; H05K 3/366; H01R 43/0256; H05K 2201/10318

(57) ABSTRACT

A printed circuit board corner connector designed to connect a first printed circuit board to a second printed circuit board, having a substantially flat contact body, from which a first connection end for connecting to the first printed circuit board extends, wherein two soldering pins for producing a soldered connection to the second printed circuit board protrude from a lateral surface of the contact body, wherein depressions are provided on lateral surface lying opposite lateral surface in positions corresponding to the soldering pins.

### RELATED APPLICATIONS

This application claims priority to and is a 35 U.S.C. § 371 national phase application of PCT/EP2020/079487, filed Oct. 20, 2020, and claims priority to German Patent Application No. 10 2020 104 100.4, filed Feb. 17, 2020, the entire contents of which are incorporated herein by reference in their entirety.

### FIELD

The disclosure relates to a printed circuit board corner connection with a press-in contact as well as an assembly of one or more printed circuit board corner connections or board edge press-in contacts mounted on or along an edge of a printed circuit board.

### BACKGROUND

A plurality of so-called board edge contacts is known from the prior art. Board edge or other types of connection mounts comprise contacts with one or more bent, self-supporting main contact arms and one or more self-supporting parallel arms for mounting on a board edge, wherein both sets of arms extend away from a common body in a common or different direction. U.S. Pat. No. 4,275,944 A discloses, for example, a so-called card edge connector.

Similar contacts are known which are designated as a built-in socket, in particular for printed circuits with fork springs housed in recess openings of the socket body, the ends of the fork springs leading out of the socket body on the back side as solder lugs. It is already known with these built-in sockets to insert the fork springs from the front side of the socket body into continuous recess openings and to laboriously bend the ends of same protruding from the socket body into solder lugs by means of suitable tools. It is further known to provide groove-shaped recesses or the like in the region of the back side, into which recesses the bent end of the fork springs engage. Apart from the fact that the bending and crimping work with the known built-in sockets leads to great complexity in production, the known built-in sockets additionally require a plug-through sleeve in the printed circuit board, which plug-through sleeve supports a solder plug for the soldering. Thus, DE 2203513 A also relates to such contact systems.

The problems in producing such contact systems increase fundamentally as soon as the bends and the dimensions as well as the materials used set limits with respect to production such that the result is unsatisfactory or has defects, which are to be avoided. Furthermore, high-performance copper alloys cannot be bent into tight radii. They can tear or the tight bending angles are not tolerated to the extent that comparatively great tolerances disadvantageously result for the printed circuit board assembly.

### BRIEF SUMMARY

The present disclosure provides an improved contact system, especially for high-temperature-resistant connections mounted at an angle to one another, such as 90° connections of a daughterboard to a motherboard.

The present disclosure provides a contact system that can subsequently seal off such connection solutions at a later time such that the conceptual solution must be suitably configured.

The present disclosure overcomes said disadvantages and provides an electrical printed circuit board corner connection which is economical to produce and optimized as relates to the material and to enable a reliable and long-term connection. Slight position tolerances should be implementable providing an assembly in the pick-and-place process with assembly robots which is improved as compared to conventional solutions.

As a whole, the ease of assembly and processability is improved, which should take place in particular with respect to known CuNiSi materials. Thus, a higher temperature resistance of a new connection system is desired having a resistance up to temperatures greater than 125° C. and significantly higher.

The objects are achieved by the combination of features according to claim 1.

To this end, according to the disclosure, a printed circuit board corner connector is provided, which is designed to connect a first printed circuit board to a second printed circuit board, comprising a substantially flat contact body, from which a first connection end for connecting to the first printed circuit board extends and wherein two soldering pins for producing a soldered connection to the second printed circuit board protrude from a lateral surface of the contact body, wherein depressions are provided on the lateral surface lying opposite the lateral surface in positions corresponding to the soldering pins.

The type of positioning of the soldered parts on the printed circuit board by means of two presented pins in this case is an especially beneficial solution as compared to the known solution which requires bent arms and leads to said production problems, which are reliably prevented with the concept of the disclosure. The shape and size of the pins or the soldering pins in this case can be targeted to the application.

Especially advantageously in this case is a solution in which the soldering pins protrude from a central region of the flat contact body in an integral manner. This can thereby be implemented in an especially beneficial manner in that the flat contact body has a basic shape that is substantially rectangular and the pins are pushed out of the contact body by means of a forming process.

In one preferred embodiment of the disclosure, it is provided that the flat contact body has a substantially rectangular basic shape, wherein respectively lateral overhangs or widenings (widened portions), preferably with a side wall having a somewhat cylindrical shape, are provided in the region of the soldering pins. This represents a form that is especially beneficial with regard to the material.

Especially advantageous is a solution in which the soldering pins protrude from a central region of the flat contact body in the manner of a crater and form a substantially cylindrical or tapered casing surface.

This can take place in an especially beneficial manner using a pressing process, stamping process, or deep-drawing process, in which, however, the stamping is not completely through the material, but rather the material deformation is carried out in a targeted manner such that the material is specifically deformed from the solid material in the region of contact body so that the desired pin shape is obtained in this case.

In an especially suitable manner, this can also take place using an embossing operation or, in a terminological sense, by means of an embossing process with an embossing tool.

In general terms, the pressing out of the two pins can take place in a manner similar to that of an incompletely stamped-through hole, wherein the stamp in this case is somewhat larger than the corresponding hole cut in the circuit board and only about 65% to 75% is pressed into the material.

It is likewise advantageous if the end face of the soldering pins is flat or substantially flat and the two end-face surfaces lie in a common parallel plane as relates to the lateral surface of the contact body, whereby good assembly into a soldering position can take place.

In a further advantageous embodiment of the disclosure, it is thus provided that the first connection end is formed as a press-in connector consisting of two legs extending next to one another, which legs extend toward one another on the end-face ends thereof or are integrally connected to one another there. This press-in connection can be inserted, for example, into a press-in socket of a motherboard.

It is further advantageous if the first connection end extends laterally away from the printed circuit board corner connector in an extension direction which is oriented at an angle of 90° with respect to the extension direction or the axis through the pins, such that a 90° connection can be implemented between the first and the second printed circuit board when the respective connection ends are properly inserted into the connection openings provided for this purpose on the printed circuit board surface.

A further aspect of the disclosure relates to a board connection assembly with a plurality similar to the previously described printed circuit board corner connectors, wherein the respective printed circuit board corner connectors are at least connected to a printed circuit board electrically via the respective pins and a common overmold made of an insulating plastic is applied around said connections.

Furthermore, an arrangement in which the two pins are flush with the extension direction of the first connection end is preferable.

A further aspect of the disclosure relates to a board connection assembly between a first and a second printed circuit board with at least one printed circuit board corner connector, wherein the lateral surfaces of the printed circuit boards are aligned or oriented at an angle of 90° with respect to one another. This results in compact solutions of motherboards with daughterboards.

### BRIEF DESCRIPTION OF THE DRAWINGS

Other advantageous further embodiments of the disclosure are characterized in the dependent claims and/or are shown in more detail in the following by means of the figures, along with the description of the preferred embodiment of the disclosure.

The following is shown:

FIG. 1 perspective views of an exemplary embodiment of a printed circuit board corner connector;

FIG. 2 perspective views of an alternative exemplary embodiment of a printed circuit board corner connector;

FIG. 3 a top view of the exemplary embodiment from FIG. 1 with a printed circuit board;

FIG. 4 a lateral view of the exemplary embodiment from FIG. 1; and

FIG. 5 a board connection assembly with 3 exemplary printed circuit board corner connectors.

### DETAILED DESCRIPTION

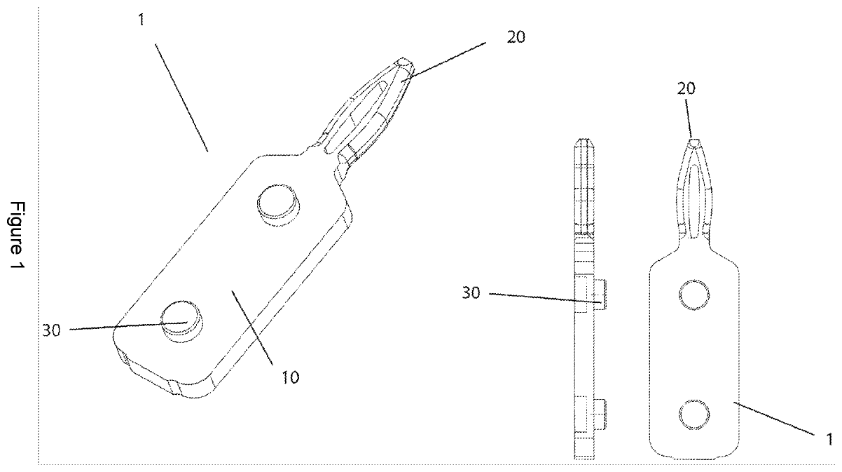

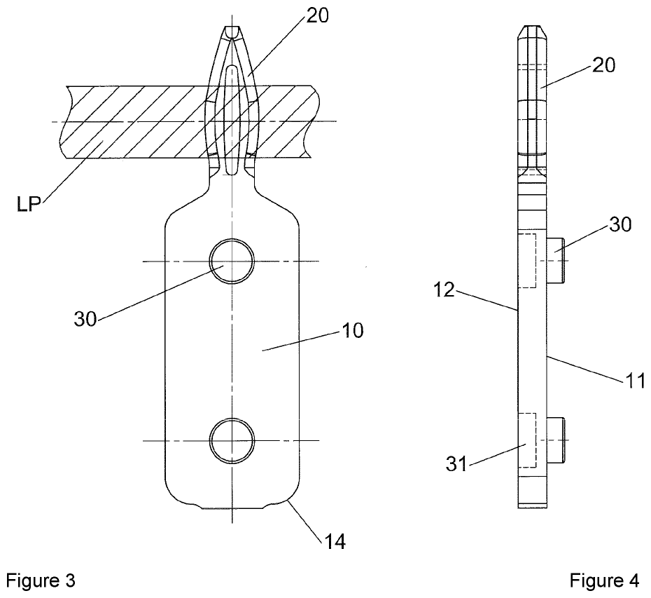

The disclosure is explained in more detail in the following with reference to FIGS. 1 to 5, wherein use of the same reference numerals in the figures indicates the same structural and/or functional features.

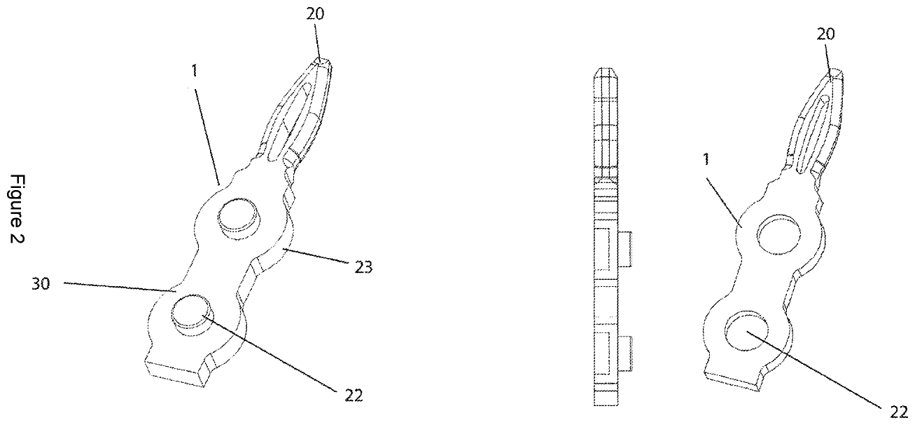

FIGS. 1 and 2 show two different exemplary embodiments of a printed circuit board corner connector 1.

The respective printed circuit board corner connector 1 is designed for connecting a first printed circuit board LP to a second printed circuit board LP comprising a substantially flat contact body 10. This contact body 10 contains a respective first connection end 20 in the form of a press-on connector for connecting to one of the printed circuit boards. Two soldering pins 30 protrude laterally from the lateral surface 11 of the respective contact body 10, which soldering pins are formed for producing a soldered connection with the other printed circuit board. The soldering pins 30 may be round, oval, squared, or star-shaped or provided with solder flank structures, e.g. with external bars.

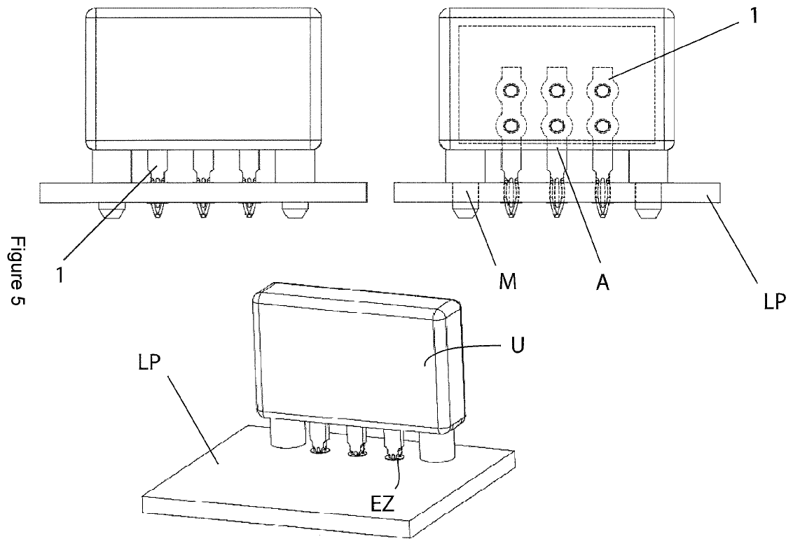

As can be easily seen in FIG. 4, two depressions 31 are indicated in lateral surface 12 opposite lateral surface 11, which depressions are formed on the other side in corresponding positions as relates to the soldering pins 30. The soldering pins 30 in this case integrally protrude from the central region B of the flat contact body 10. As can be seen in FIGS. 1 and 2, the soldering pins 30 protrude in the manner of a crater from a central region of the flat contact body 10 and have a substantially cylindrical casing surface.

In the exemplary embodiment of FIG. 1, the flat contact body 10 has a substantially rectangular basic shape with rounded corners 14.

In the exemplary embodiment of FIG. 2, the flat contact body 10 has a substantially rectangular basic shape, wherein respectively lateral overhangs or widenings 22 are provided in the region of the soldering pins 20, and that is with a somewhat cylindrically shaped side wall 23.

FIG. 5 shows a board connection assembly with a plurality of 3 printed circuit board corner connectors 1 mounted on a printed circuit board LP. The board connection assembly comprises a sealing overmold U, which seals off the circuit board corner connector on a flat bar section SA thereof. The printed circuit board corner connectors 1 are pressed, with the press-in section thereof, into the press-in zones EZ in the printed circuit board LP. In addition, assembly aids M are provided with which the overmold U is mounted on the printed circuit board, preferably with mechanical support.

The disclosure is not limited in its design to the aforementioned preferred exemplary embodiments. Rather, a number of variants is conceivable, which would make use of the solution shown even with essentially different designs.

1. A printed circuit board corner connector which is configured to connect a first printed circuit board to a second printed circuit board, the printed circuit board corner connector comprising a substantially flat contact body, from which a first connection end for connecting to the first printed circuit board extends and wherein two soldering pins for producing a soldered connection to the second printed circuit board protrude from a lateral surface of the contact body, wherein depressions are provided on an opposing lateral surface lying opposite the lateral surface in positions corresponding to the soldering pins.

2. The printed circuit board corner connector according to claim 1, wherein the soldering pins integrally protrude from a central region of the flat contact body.

3. The printed circuit board corner connector according to claim 1, wherein the flat contact body has a substantially rectangular basic shape, preferably with rounded corners.

4. The printed circuit board corner connector according to claim 1, wherein the flat contact body has a substantially rectangular shape, wherein lateral overhangs or widenings, having a side wall with a somewhat cylindrical shape, are respectively provided in the region of the soldering pins.

5. The printed circuit board corner connector according to claim 1, wherein the soldering pins protrude from a central region of the flat contact body in the manner of a crater and form a substantially cylindrical or tapered casing surface.

6. The printed circuit board corner connector according to claim 1, wherein the soldering pins are produced using a pressing process, a stamping process, or a deep-drawing process.

7. The printed circuit board corner connector according to claim 1, wherein the end face of the soldering pins is substantially flat and the two end-face surfaces lie in a common parallel plane with respect to the lateral surface of the contact body.

8. The printed circuit board corner connector according to claim 1, wherein the first connection end is formed as a press-in connector consisting of two legs extending next to one another, which legs extend toward one another on end-face ends thereof or are integrally connected to one another at their end-face ends.

9. The printed circuit board corner connector according to claim 1, wherein the first connection end extends laterally away from the printed circuit board corner connector in an extension direction which is oriented at an angle of 90° with respect to an extension direction or an axis through the pins, such that a 90° connection can be implemented between the first and the second printed circuit board when the respective connection ends are inserted into the connection openings provided for this orientation on the printed circuit board surface.

10. A board connection assembly with a plurality of printed circuit board corner connectors, according to claim 1, wherein the respective printed circuit board corner connectors are at least connected to a printed circuit board electrically via the pins and a common overmold made of an insulating plastic is applied around said connections.

11. The board connection assembly according to claim 10, wherein the printed circuit board corner connectors with the sections thereof having the soldering pins are jointly and fully overmolded with the printed circuit board LP.

12. A board connection assembly between a first and a second printed circuit board having at least one printed circuit board corner connector according to claim 1, wherein the lateral surfaces of the printed circuit boards are aligned or oriented at an angle with respect to each other.

12. The board connection assembly according to claim 12, wherein the lateral surfaces of the printed circuit boards are aligned or oriented at an angle of 90° with respect to each other.
